(19) United States
(12) Patent Application Publication
(10) Pub. No.: US 2026/0343112 A1
(43) Pub. Date: Oct. 29, 2026

(54) IMAGE SENSING DEVICE

(71) Applicant: SK hynix Inc., Gyeonggi-do (KR)

(72) Inventor: Yuuki ADACHI, Tokyo (JP)

(21) Appl. No.: 19/367,819

(22) Filed: Oct. 24, 2025

(30) Foreign Application Priority Data
Apr. 25, 2025 (KR) 10-2025-0054886

(51) Int. Cl. H04N 25/46; H04N 25/704; H10F 39/00

(52) U.S. Cl. CPC H04N 25/46; H04N 25/704; H10F 39/8027; H10F 39/8063

(57) ABSTRACT

An image sensing device includes a plurality of pixel blocks, each of which includes a plurality of pixel groups arranged in a Bayer pattern; a binning circuit configured to bin pixels included in the plurality of pixel groups; and a phase-difference adjuster configured to generate a left image and a right image based on images received from the plurality of pixel blocks and the binning circuit, and configured to adjust a baseline length between the left image and the right image. Each of the plurality of pixel groups includes a first pixel having a first photosensitivity and a plurality of second pixels having a second photosensitivity. The phase-difference adjuster includes a baseline adjuster configured to adjust the baseline length between the first pixels located in different pixel blocks among the plurality of pixel blocks.

### CROSS-REFERENCE TO RELATED APPLICATION

This patent application claims the priority and benefits of Korean patent application No. 10-2025-0054886, filed on Apr. 25, 2025, the disclosure of which is incorporated by reference in its entirety.

### TECHNICAL FIELD

The technology and embodiments of the present disclosure generally relate to an image sensing device capable of generating parallax images.

### BACKGROUND

In general, CMOS (Complementary Metal Oxide Semiconductor) image sensing devices, which are implemented using the CMOS process, are devices that capture optical images using the properties of photosensitive semiconductor materials that react to light. With the development of automotive, medical, computer and communication industries, the demand for high-performance image sensing devices is increasing in various fields such as smartphones, digital cameras, game machines, IoT (Internet of Things), robots, security cameras and medical micro cameras.

For a device (e.g., a camera) for photographing a target object, it is important to accurately focus on the target object to capture a clear image (e.g., a still image) or video (e.g., moving images). To improve autofocus accuracy, there is a need to reduce the amount of parallax between parallax images.

### SUMMARY

Various embodiments of the present disclosure relate to an image sensing device capable of reducing the amount of parallax between a high-sensitivity image and a low-sensitivity image for use in an image sensor including high-sensitivity pixels and low-sensitivity pixels in order to generate a high dynamic range (HDR) image.

In accordance with an embodiment of the present disclosure, an image sensing device may include a plurality of pixel blocks, each of which includes a plurality of pixel groups arranged in a Bayer pattern; a binning circuit configured to bin pixels included in the plurality of pixel groups; and a phase-difference adjuster configured to generate a left image and a right image based on images received from the plurality of pixel blocks and the binning circuit, and configured to adjust a baseline length between the left image and the right image. Each of the plurality of pixel groups may include a first pixel having a first photosensitivity and a plurality of second pixels having a second photosensitivity. The phase-difference adjuster may include a baseline adjuster configured to adjust the baseline length between the first pixels located in different pixel blocks among the plurality of pixel blocks.

It is to be understood that both the foregoing general description and the following detailed description of the present disclosure are illustrative and descriptive and are intended to provide further description of the embodiments of the present disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a block diagram illustrating an imaging device based on some embodiments of the present disclosure.

FIG. 2 is a diagram illustrating a case in which a length of a baseline (i.e., a baseline length) between pixels is not adjusted according to an arrangement pattern of pixels in a pixel group based on some embodiments of the present disclosure.

FIG. 3 is a block diagram illustrating the image sensing device shown in FIG. 1 based on some embodiments of the present disclosure.

FIG. 4 is a diagram illustrating a structure in which pixel blocks are consecutively arranged in the pixel array shown in FIG. 3 based on some embodiments of the present disclosure.

FIG. 5 is a diagram illustrating a structure of a one pixel sub-block in the pixel array shown in FIG. 4 based on some embodiments of the present disclosure.

FIGS. 6A to 6D are diagrams illustrating structures in which pixel blocks of FIGS. 4 and 5 are consecutively arranged based on some embodiments of the present disclosure.

FIGS. 7A to 7D are diagrams illustrating operations for describing an offset of a pixel group in an offset setting circuit of FIG. 3 based on some embodiments of the present disclosure.

FIG. 8 is a diagram illustrating operations for a phase-difference adjuster of FIG. 3 based on some embodiments of the present disclosure.

FIGS. 9A to 9C are diagrams illustrating operations for a sign adjuster of FIG. 3 based on some embodiments of the present disclosure.

### DETAILED DESCRIPTION

Embodiments of the present disclosure provide an image sensing device capable of generating parallax images that may be used in configurations to substantially address one or more technical or engineering issues and to mitigate limitations or disadvantages encountered in some imaging devices in the art. Some embodiments of the present disclosure relate to an image sensing device that can reduce the amount of parallax between a high-sensitivity image and a low-sensitivity image for use in an image sensor including high-sensitivity pixels and low-sensitivity pixels to generate a high dynamic range (HDR) image. In recognition of the issues above, the image sensing device according to the embodiments of the present disclosure can improve autofocus accuracy by reducing the amount of parallax between the high-sensitivity image and the low-sensitivity image.

Reference will now be made in detail to some embodiments of the present disclosure which are illustrated in the accompanying drawings. Wherever possible, the same reference numbers will be used throughout the drawings to refer to the same or like parts. While the embodiments of the present disclosure are susceptible to various modifications and alternative forms, specific embodiments thereof are shown in the drawings. However, the embodiments should not be construed as being limited to the specific embodiments set forth herein.

Hereinafter, various embodiments will be described with reference to the accompanying drawings. However, it should be understood that the embodiments are not limited to specific embodiments, but include various modifications, equivalents and/or alternatives of the embodiments. The embodiments of the present disclosure may provide a variety of advantageous effects capable of being directly or indirectly recognized by one of ordinary skill in the art.

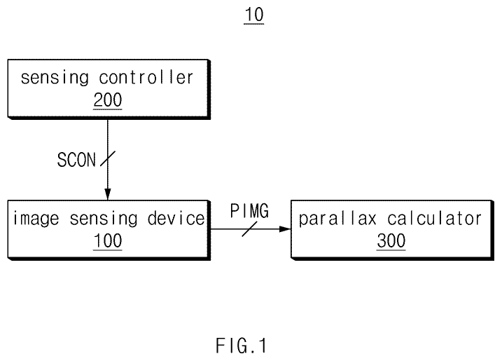

FIG. 1 is a block diagram illustrating an imaging device 10 based on some embodiments of the present disclosure.

Referring to FIG. 1, the imaging device 10 may include an image sensing device 100, a sensing controller 200, and a parallax calculator 300.

Here, the image sensing device 100 may capture a subject and convert an optical signal for the captured subject into an electrical signal to generate a parallax image (PIMG). For example, the image sensing device 100 may include a plurality of pixels that capture a subject and convert an optical signal obtained by capturing the subject into an electrical signal (pixel signal), and may convert pixel signals output from the plurality of pixels into digital signals using an analog-to-digital converter (ADC) to generate a parallax image (PIMG).

Here, the term “parallax” (or disparity) may represent a difference in position or direction of the subject according to observation positions. A parallax image may refer to an image in which a parallax value calculated for each of the pixels on a reference image is used as a pixel value of each pixel.

The plurality of pixels may include high-sensitivity pixels and low-sensitivity pixels for high dynamic range (HDR) imaging.

In this case, each of the high-sensitivity pixels may refer to a pixel having a relatively large increase in response due to an increase in the intensity of incident light. Here, the term “response” may refer to a pixel signal generated by the high-sensitivity pixels detecting the intensity of incident light. Each of the high-sensitivity pixels may refer to a pixel having a relatively high photosensitivity to incident light. Each of the low-sensitivity pixels may refer to a pixel having a relatively small increase in response due to an increase in the intensity of incident light. Each of the low-sensitivity pixels may refer to a pixel having a relatively low photosensitivity to incident light.

The high-sensitivity pixels and the low-sensitivity pixels may have sensing conditions changed based on a control signal (SCON) of the sensing controller 200. A signal generated by some of the high-sensitivity pixels or the low-sensitivity pixels may be used as a signal for autofocus.

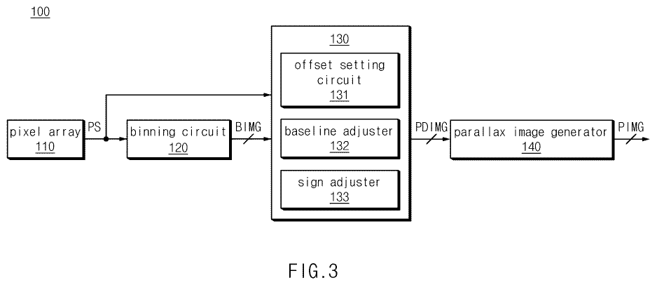

For example, the image sensing device 100 may generate parallax images (PIMG) for autofocus. The parallax images (PIMG) may include a high-sensitivity parallax image generated using signals from some of the high-sensitivity pixels or a low-sensitivity parallax image generated using pixel signals from some of the low-sensitivity pixels. The configuration and operation of the image sensing device 100 will be described in more detail later with reference to FIGS. 3 to 9C.

In addition, the sensing controller 200 may generate a control signal (SCON) according to a preset logic. The sensing controller 200 may control at least one of an exposure time, a conversion gain, and an analog gain of the image sensing device 100 based on the control signal (SCON). For example, the sensing controller 200 may include position information (i.e., position information within the pixel array) for preset high-sensitivity pixels and preset low-sensitivity pixels. The sensing controller 200 may control at least one of the exposure time, conversion gain, and analog gain of the high-sensitivity pixels and the low-sensitivity pixels based on the position information to allow the image sensing device 100 to generate an HDR (High Dynamic Range) image.

The parallax calculator 300 may calculate a horizontal parallax (i.e., a first-directional parallax) or a vertical parallax (i.e., a second-directional parallax) for the image sensing device 100 using the parallax images (PIMG) received from the image sensing device 100. Here, the parallax calculator 300 may calculate the horizontal parallax or the vertical parallax by comparing high-sensitivity parallax images with each other or by comparing low-sensitivity parallax images with each other.

For example, the parallax calculator 300 may calculate the horizontal parallax by comparing at least two high-sensitivity parallax images (e.g., a left high-sensitivity parallax image and a right high-sensitivity parallax image) in the horizontal direction with each other. The parallax calculator 300 may calculate the horizontal parallax by comparing at least two low-sensitivity parallax images (e.g., a left low-sensitivity parallax image and a right low-sensitivity parallax image) in the horizontal direction with each other.

In some embodiments, the parallax calculator 300 may calculate the vertical parallax by comparing at least two high-sensitivity parallax images (e.g., a top high-sensitivity parallax image and a bottom high-sensitivity parallax image) in the vertical direction with each other. The parallax calculator 300 may calculate the vertical parallax by comparing at least two low-sensitivity parallax images (e.g., a top low-sensitivity parallax image and a bottom low-sensitivity parallax image) in the vertical direction with each other.

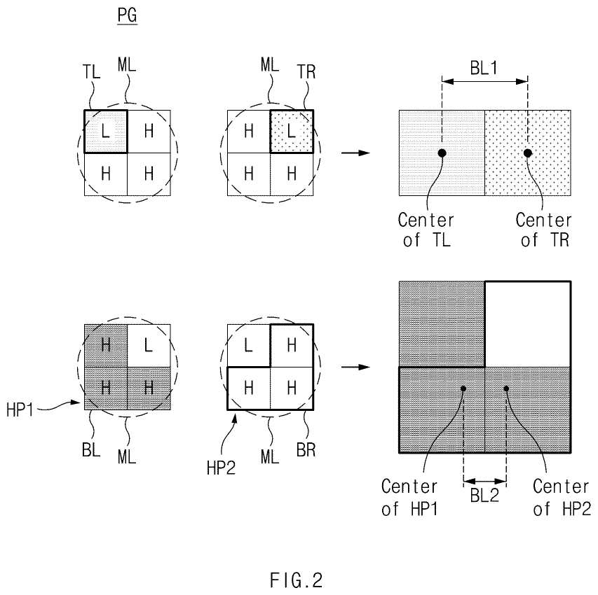

FIG. 2 is a diagram illustrating a case in which the length of a baseline (hereinafter referred to as a baseline length) between pixels is not adjusted according to the arrangement pattern of the pixels within a pixel group (PG) based on some embodiments of the present disclosure. In FIG. 2, the pixel group (PG) including four green (G) pixels arranged in a (2×2) matrix structure will be described as an example.

The image sensing device 100 may include a phase-difference detection autofocus (PDAF) function that automatically focuses by detecting a phase difference between adjacent pixels. The phase difference detection autofocus method is a method of measuring an offset direction and an offset amount from a center image obtained through the image sensing device 100 using a phase difference between two or more different distance measurement points. In addition, to improve the PDAF function, a structure in which a plurality of pixels of the same color is arranged adjacent to each other and one microlens (ML) is applied to the plurality of pixels is used in the image sensing device 100.

For example, among the four green pixels (G) of the pixel group (PG), “TL” may represent a pixel located at a top-left position, “TR” may represent a pixel located at a top-right position, “BL” may represent a pixel located at a bottom-left position, and “BR” may represent a pixel located at a bottom-right position. The TL pixel and the TR pixel may be adjacent to each other in the first direction (i.e., the horizontal direction). The BL pixel and the BR pixel may be adjacent to each other in the first direction (i.e., the horizontal direction). The TL pixel and the BL pixel may be adjacent to each other in the second direction (i.e., the vertical direction). The TR pixel and the BR pixel may be adjacent to each other in the second direction (i.e., the vertical direction). Four pixels (TL, TR, BL, BR) included in one pixel group (PG) may share one microlens (ML).

However, the image sensing device having a structure in which a single microlens (ML) is applied to multiple pixels may have difficulty in accurately performing autofocus due to differences in parallax caused by factors such as astigmatism of a lens. In particular, the parallax calculator 300 may compare high-sensitivity parallax images with each other, or may compare low-sensitivity parallax images with each other, so that the parallax calculator 300 can calculate a horizontal parallax or a vertical parallax. However, the baseline length between the high-sensitivity parallax images and the baseline length between the low-sensitivity parallax images may be changed, so that the parallax may not be accurately calculated.

For example, a left parallax image may be generated using the top-left low-sensitivity pixel (TL) located at the top-left side in the pixel group (PG), and a right parallax image may be generated using the top-right low-sensitivity pixel (TR) located at the top-right side in the pixel group (PG). Here, the length between the center of the low-sensitivity pixel (TL) and the center of the low-sensitivity pixel (TR) may be defined as “BL1”.

In addition, at least three high-sensitivity pixels (HP1) arranged in a “└” shape may be binned to generate a left parallax image, and at least three high-sensitivity pixels (HP2) arranged in a “┘” shape may be binned to generate a right parallax image. Here, the baseline length between the center of the high-sensitivity pixels (HP1) and the center of the high-sensitivity pixels (HP2) may be defined as “BL2”.

However, the baseline length (BL2) between the high-sensitivity pixels (HP1, HP2) and the baseline length (BL1) between the low-sensitivity pixels (TL, TR) may be different from each other. That is, the baseline length (BL2) between the high-sensitivity pixels (HP1, HP2) may be shorter than the baseline length (BL1) between the low-sensitivity pixels (TL, TR). Accordingly, the amount of parallax may be reduced in the high-sensitivity parallax image, which makes the amount of parallax greater between the high-sensitivity parallax image and the low-sensitivity parallax image, so that autofocus may not be performed properly.

Therefore, the embodiments of the present disclosure may adjust the baseline lengths of low-sensitivity images (or high-sensitivity images) to match the baselines of high-sensitivity images (or low-sensitivity images). Thus, the embodiments can improve the autofocus accuracy by reducing the amount of parallax between the high-sensitivity parallax image and the low-sensitivity parallax image. A detailed operation of the image sensing device according to the embodiments of the present disclosure will be described hereinbelow in more detail with reference to FIGS. 3 to 9C.

FIG. 3 is a block diagram illustrating the image sensing device 100 shown in FIG. 1 based on some embodiments of the present disclosure.

Referring to FIG. 3, the image sensing device 100 may include a pixel array 110, a binning circuit 120, a phase-difference adjuster 130, and a parallax image generator 140. The constituent components of the image sensing device 100 illustrated in FIG. 1 are discussed by way of illustration only, and the embodiments of the present disclosure encompass numerous other changes, substitutions, variations, alterations, and modifications. In the present disclosure, the word “pixel” can be used to indicate an image sensing pixel that is structured to detect incident light to generate electrical signals carrying images in the incident light.

The pixel array 110 may include a plurality of pixels arranged in a plurality of rows and a plurality of columns. In an embodiment, the plurality of pixels may be arranged in a two-dimensional (2D) pixel array including rows and columns. In another embodiment, the plurality of pixels may be arranged in a three-dimensional (3D) pixel array. The plurality of pixels may be grouped into pixel groups.

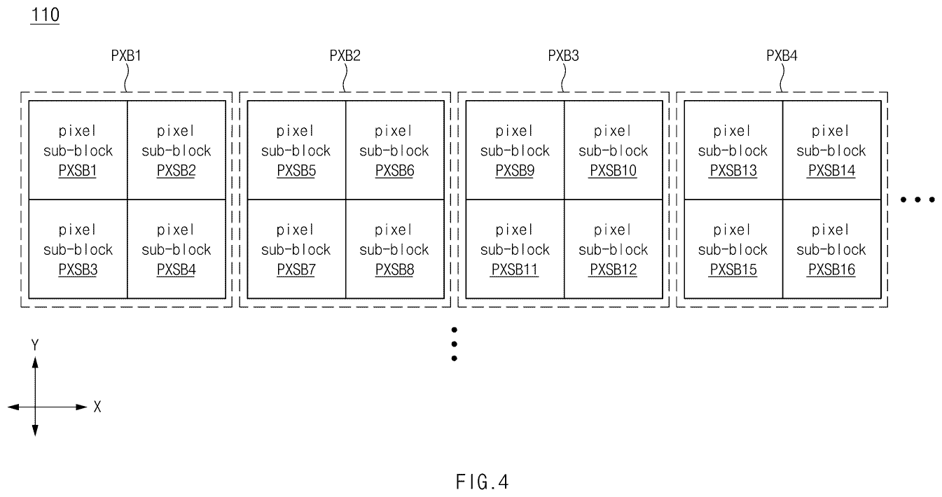

The plurality of pixels may convert an optical signal into an electrical signal either on a pixel basis or a pixel group basis, and may output a pixel signal (PS). For example, the pixel array 110 may include high-sensitivity pixels and low-sensitivity pixels. The pixel signal (PS) may include a high-sensitivity pixel signal detected by the high-sensitivity pixels and a low-sensitivity pixel signal detected by the low-sensitivity pixels. The configuration of the pixel array 110 will be described in more detail later with reference to FIGS. 4 to 6D.

The binning circuit 120 may perform binning of the pixel signal (PS) received from the pixel array 110, may convert the binned pixel signal into a digital signal, and may generate binning images (BIMG). Here, the term “binning” may refer to a process of compressing data by discarding some of data acquired through all pixels or summing some of data acquired through all pixels and other data, when the resolution of a required image can be implemented with only some of all pixels of the image sensor.

In some embodiments, the binning circuit 120 may generate binning images (BIMG) by summing the pixel signal (PS) received from the pixel array 110 and converting the summed pixel signal (PS) into a digital signal. Here, the term “summing” may refer to a process of summing (or averaging) the pixel values (or pixel signals) of the pixels.

In the present disclosure, as an example, the binning circuit 120 will be described as performing binning of the pixel signal (PS) for convenience of description and better understanding of the present disclosure. For example, the binning circuit 120 may generate a high-sensitivity image by binning at least three high-sensitivity pixel signals to adjust a parallax amount. In some embodiments, in order to adjust the amount of parallax, the binning circuit 120 may generate a low-sensitivity image by binning at least three low-sensitivity pixel signals to generate an HDR image. Here, the high-sensitivity image and the low-sensitivity image may be included in the binning images (BIMG) described above. In the present disclosure, a case in which the binning circuit 120 generates the binning images (BIMG) by binning at least three high-sensitivity pixel signals will be described.

The phase-difference adjuster 130 may generate phase-difference images (PDIMG) by adjusting a phase difference between the high-sensitivity images and the low-sensitivity images. In this case, the phase-difference adjuster 130 may include an offset setting circuit 131, a baseline adjuster 132, and a sign adjuster 133.

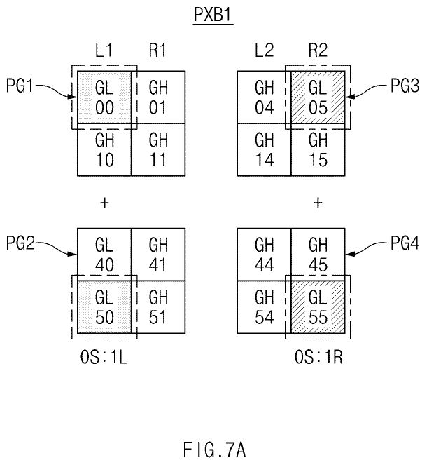

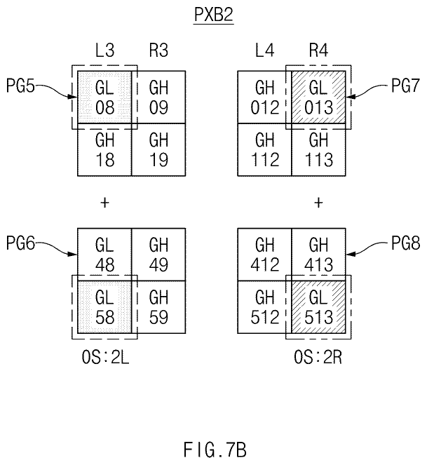

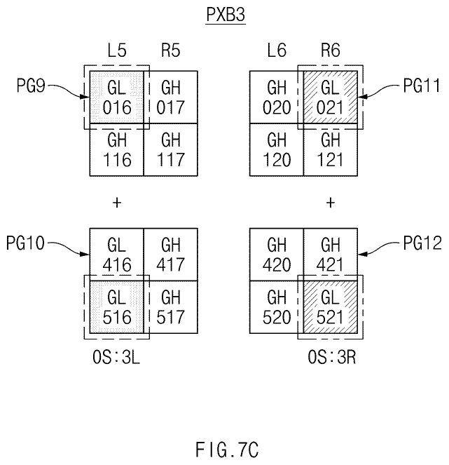

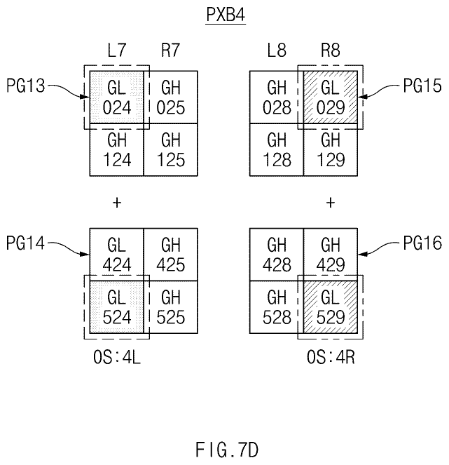

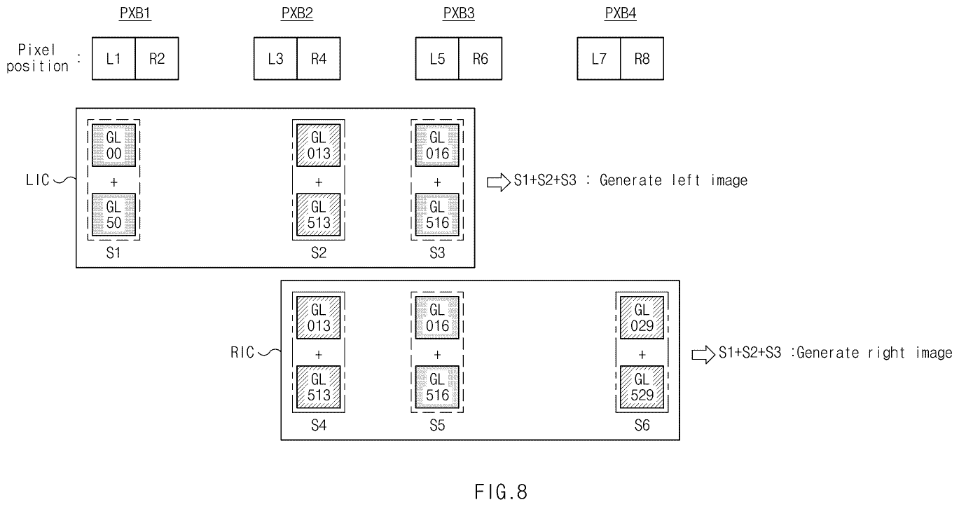

The offset setting circuit 131 may set an offset differently based on positions of the pixels. For example, the offset setting circuit 131 may set the position of the low-sensitivity pixel as a reference position. The offset setting circuit 131 may set an offset differently according to the distance at which other pixels are located from the position of the reference pixel. The detailed operation of the offset setting circuit 131 will be described hereinbelow in more detail with reference to FIGS. 7A to 8.

The baseline adjuster 132 may adjust the baseline length of high-sensitivity images or the baseline length of low-sensitivity images to generate phase-difference images (PDIMG). For example, the baseline adjuster 132 may obtain the baseline length of the left image and the baseline length of the right image. In addition, the baseline adjuster 132 may adjust the baseline length in a direction toward an image having a shorter baseline length among the left image and the right image. The detailed configuration and operation of the baseline adjuster 132 will be described hereinbelow in more detail with reference to FIG. 8.

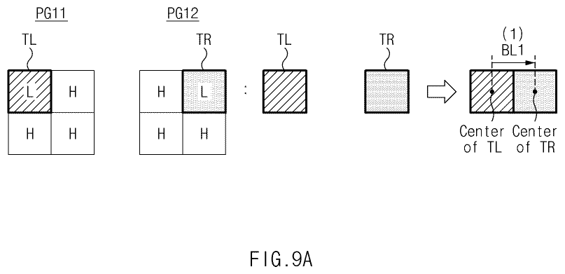

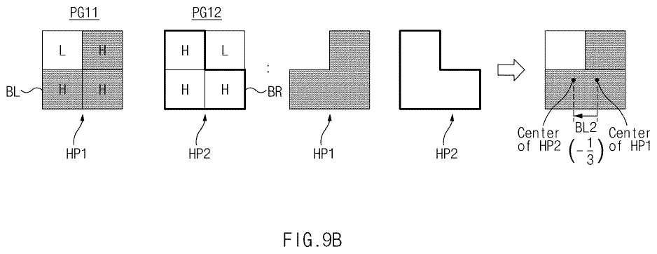

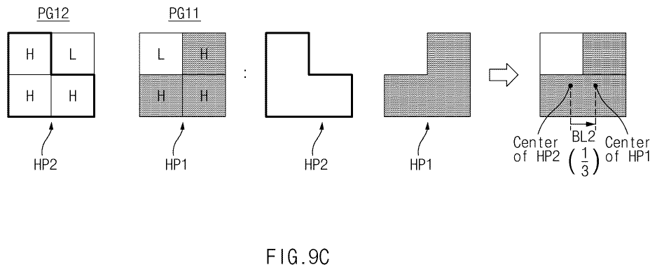

The sign adjuster 133 may adjust the sign when the sign that serves as a reference value for disparity calculation in an array structure of phase-difference images (PDIMG) is inverted. The detailed configuration and operation of the sign adjuster 133 will be described hereinbelow in more detail with reference to FIGS. 9A to 9C.

The parallax image generator 140 may generate parallax images (PIMG) by aligning the phases of phase-difference images (PDIMG). Here, the parallax images (PIMG) may include high-sensitivity parallax images and low-sensitivity parallax images.

For example, the parallax image generator 140 may generate at least two high-sensitivity parallax images (e.g., a left high-sensitivity parallax image and a right high-sensitivity parallax image) in the horizontal direction. The parallax image generator 140 may generate at least two low-sensitivity parallax images (i.e., a left low-sensitivity parallax image and a right low-sensitivity parallax image) in the horizontal direction.

In some embodiments, the parallax image generator 140 may generate at least two high-sensitivity parallax images (e.g., a top high-sensitivity parallax image and a bottom high-sensitivity parallax image) in the vertical direction. The parallax image generator 140 may generate at least two low-sensitivity parallax images (e.g., a top low-sensitivity parallax image and a bottom low-sensitivity parallax image) in the vertical direction.

FIG. 4 is a diagram illustrating a structure in which pixel blocks are consecutively arranged in the pixel array shown in FIG. 3 based on some embodiments of the present disclosure.

Referring to FIG. 4, the pixel array 110 may include a plurality of pixel blocks (PXB1~PXB4). The plurality of pixel blocks (PXB1~PXB4) may be arranged adjacent to each other in a first direction (e.g., an X-axis direction). In some embodiments, the plurality of pixel blocks (PXB1 to PXB4) may be arranged adjacent to each other in a second direction (e.g., a Y-axis direction).

The pixel blocks (PXB1~PXB4) may be arranged adjacent to each other in an (M×N) matrix structure, where “M” and “N” are integers greater than or equal to 2 and may be the same or different from each other. For example, the pixel block (PXB1) may include four pixel sub-blocks (PXSB1~PXSB4) arranged in a (2×2) matrix structure. The pixel block (PXB2) may include four pixel sub-blocks (PXSB5~PXSB8) arranged in a (2×2) matrix structure. The pixel block (PXB3) may include four pixel sub-blocks (PXSB9~PXSB12) arranged in a (2×2) matrix structure. The pixel block (PXB4) may include four pixel sub-blocks (PXSB13~PXSB16) arranged in a (2×2) matrix structure.

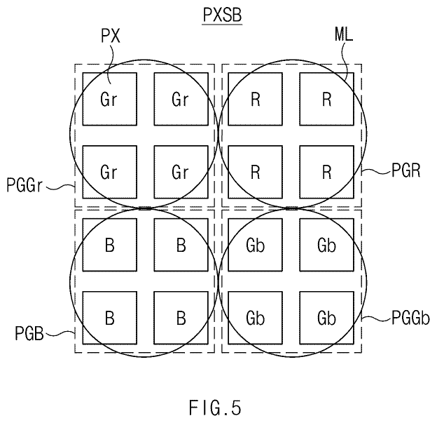

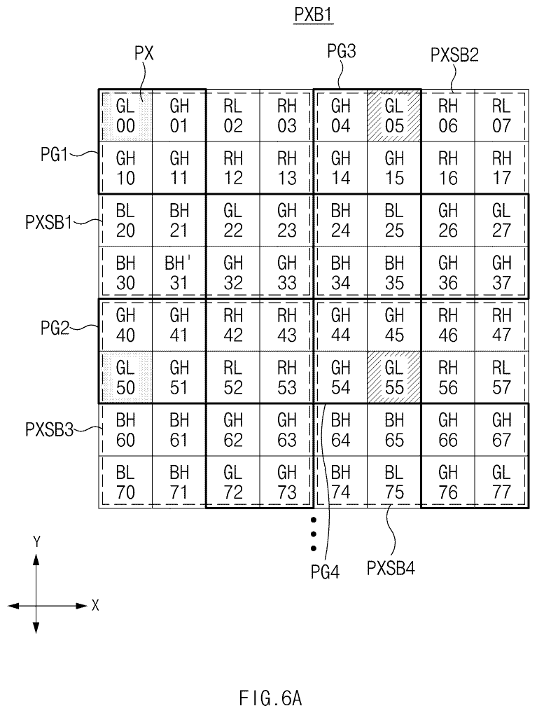

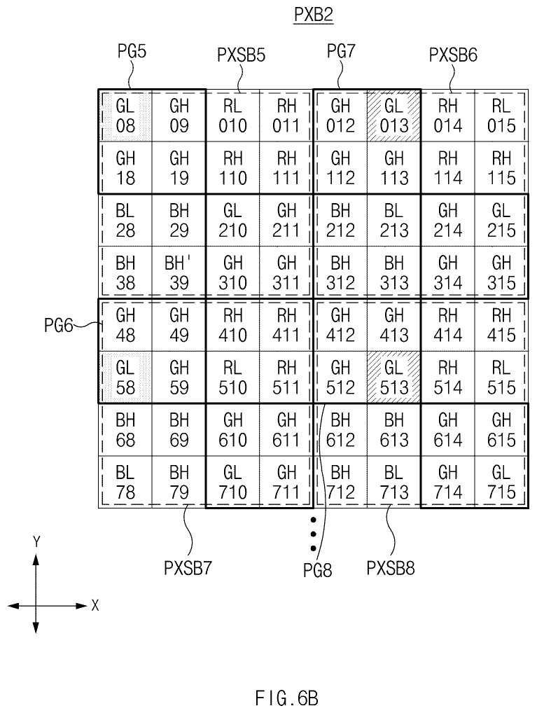

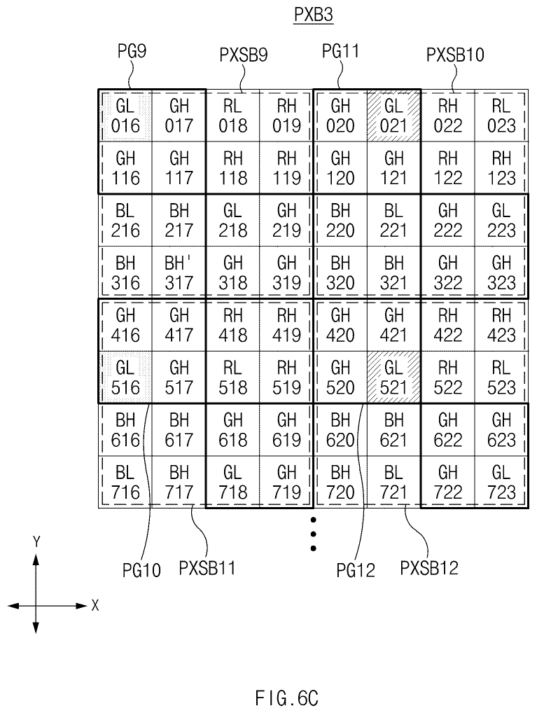

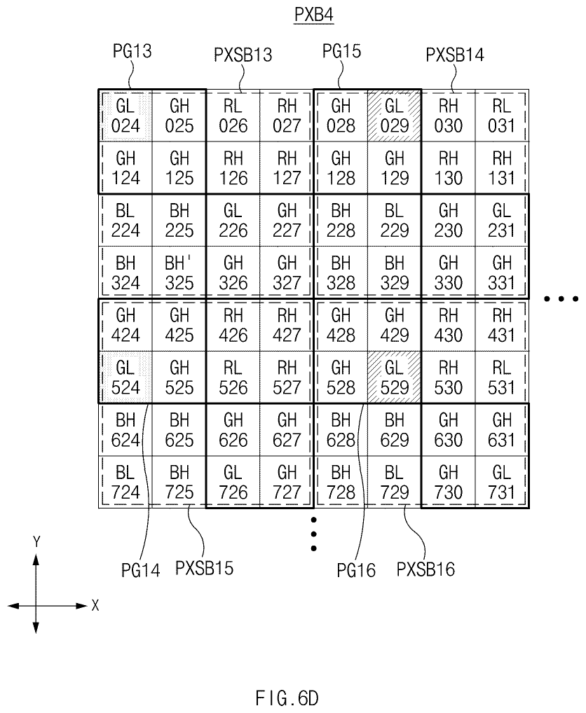

The detailed configuration of the pixel sub-blocks (PXSB) will be described hereinbelow in more detail with reference to FIGS. 5 to 6D.

FIG. 5 is a diagram illustrating a structure of a one pixel sub-block in the pixel array shown in FIG. 4 based on some embodiments of the present disclosure.

Referring to FIG. 5, each pixel sub-block (PXSB) may include a plurality of pixel groups (PGR, PGGr, PGGb, PGB) arranged adjacent to each other. Each pixel group (PGR, PGGb, PGGr, PGB) may include the plurality of pixels (PXs) that shares one microlens (ML) and has a color filter of the same color.

The pixels (PXs) of each pixel group (PGR, PGGb, PGGr, PGB) may be arranged adjacent to each other in an (M×N) matrix structure, where “M” and “N” are integers greater than or equal to 2 and may be the same or different from each other. For example, the pixel group (PGR) may include four red color (R) pixels (PXs) arranged in a (2×2) matrix structure while sharing one microlens (ML). Each of the pixel groups (PGGr, PGGb) may include four green (Gr, Gb) pixels (PXs) arranged in a (2×2) matrix structure while sharing one microlens (ML). The pixel group (PGB) may include four blue (B) pixels (PXs) arranged in a (2×2) matrix structure while sharing one microlens (ML). The pixel groups (PGR, PGGr, PGGb, PGB) may be arranged in a Bayer pattern.

In addition to the pixel groups described above, it may be understood that the remaining pixel groups of the pixel sub-block (PXSB) are also arranged in the same pattern. In addition, the arrangement pattern of the pixel groups (PGR, PGGr, PGGb, PGB) and the number of pixel groups included in each pixel sub-block (PXSB) are not limited thereto, and may also be sufficiently changed as needed.

Each pixel (PX) may include a photosensitive element that converts incident light into an electrical signal corresponding to the incident light. For example, the photosensitive element may be implemented as a photodiode, a phototransistor, a photogate, a pinned photodiode, or a combination thereof.

FIGS. 6A to 6D are diagrams illustrating structures in which pixel blocks of FIGS. 4 and 5 are consecutively arranged based on some embodiments of the present disclosure.

Referring to FIGS. 6A to 6D, each of the pixel sub-blocks (PXSB1~PXSB16) may include a plurality of pixel groups (PGs) arranged adjacent to each other in the first direction (e.g., X-axis direction) and the second direction (e.g., Y-axis direction). Four pixel groups among the plurality of pixel groups (PGs) illustrated in FIGS. 6A to 6D may correspond to the pixel sub-block (PXSB) illustrated in FIG. 5.

In the embodiments of FIGS. 6A to 6D, for convenience of description and better understanding of the present disclosure, only some pixels of green color (G) among the pixel sub-blocks (PXSB1~PXSB16) are numbered as pixel groups (PG1~P16).

For example, the sub-block (PXSB1) may include a pixel group (PG1), the sub-block (PXSB2) may include a pixel group (PG3), the sub-block (PXSB3) may include a pixel group (PG2), and the sub-block (PXSB4) may include a pixel group (PG4). The sub-block (PXSB5) may include a pixel group (PG5), the sub-block (PXSB6) may include a pixel group (PG7), the sub-block (PXSB7) may include a pixel group (PG6), and the sub-block (PXSB8) may include a pixel group (PG8).

The sub-block (PXSB9) may include a pixel group (PG9), the sub-block (PXSB10) may include a pixel group (PG11), the sub-block (PXSB11) may include a pixel group (PG10), and the sub-block (PXSB12) may include a pixel group (PG12). The sub-block (PXSB13) may include a pixel group (PG13), the sub-block (PXSB14) may include a pixel group (PG15), the sub-block (PXSB15) may include a pixel group (PG14), and the sub-block (PXSB16) may include a pixel group (PG16).

Although the embodiments of the present disclosure have disclosed the green color (G) as an example color, the scope or spirit of the present disclosure is not limited thereto, and it should be noted that the embodiments of the present disclosure can also be applied to pixels of blue color (B) or pixels of red color (R).

The plurality of pixel groups (PG1~PG16) may include high-sensitivity pixels (GH01,GH10,GH11,GH40,GH41,GH51,GH04,GH14,GH15,GH44,GH45,GH54, GH09,GH18,GH19,GH48,GH49,GH59,GH012,GH112,GH113,GH412,GH413,G H512,GH017,GH116,GH117,GH416,GH417,GH517,GH020,GH120,GH121,GH 420,GH421,GH520,GH025,GH124,GH125,GH424,GH425,GH525,GH028,GH1 28,GH129,GH428,GH429,GH528) for creating HDR images, and low-sensitivity pixels (GL00,GL50,GL05,GL55,GL08,GL58,GL013,GL513,GL016,GL516,GL021,GL521,GL024,GL524,GL029,GL529) for creating HDR images. For example, pixels (PXs) included in each pixel group (PG1~PG16) may correspond to either high-sensitivity pixels or low-sensitivity pixels. In the pixels (PXs) shown in FIGS. 6A to 6D, some pixels (PXs) denoted by “H” may correspond to high-sensitivity pixels. In the pixels (PXs) shown in FIGS. 6A to 6D, some pixels (PXs) denoted by “L” may correspond to low-sensitivity pixels.

The high-sensitivity pixels or low-sensitivity pixels of the pixel groups (PG1~PG16) may be used to generate parallax images in a first direction (e.g., a horizontal direction). The high-sensitivity pixels or low-sensitivity pixels of the pixel groups (PG1~PG16) may be used to generate parallax images in a second direction (e.g., a vertical direction).

In some embodiments, each of the pixel groups (PG1~PG16) may include three high-sensitivity pixels and one low-sensitivity pixel. The arrangement patterns of the high-sensitivity pixels and the low-sensitivity pixels between the pixel groups (PG1~PG16) adjacent to each other in the first direction in each pixel block (PXB1~PXB4) may be symmetrical to each other in the first direction. In addition, the arrangement patterns of the high-sensitivity pixels and the low-sensitivity pixels between the pixel groups (PG1~PG16) adjacent to each other in the second direction may be symmetrical to each other in the second direction.

For example, the high-sensitivity pixels (GH01, GH10, GH11, GH09, GH18, GH19, GH017, GH116, GH117, GH025, GH124, GH125) in pixel groups (PG1, PG5, PG9, PG13) may have an arrangement pattern formed in the shape of “┘”. The high-sensitivity pixels (GH04, GH14, GH15, GH012, GH112, GH113, GH020, GH120, GH121, GH028, GH128, GH129) in pixel groups (PG3, PG7, PG11, PG15) adjacent to the pixel groups (PG1, PG5, PG9, PG13) in the first direction may have an arrangement pattern formed in the shape of “└”.

High-sensitivity pixels (GH40, GH41, GH51, GH48, GH49, GH59, GH416, GH417, GH517, GH424, GH425, GH525) in the pixel groups (PG2, PG6, PG10, PG14) adjacent to the pixel groups (PG1, PG5, PG9, PG13) in the second direction may have an arrangement pattern formed in the shape of “¬”. High-sensitivity pixels (GH44, GH45, GH54, GH412, GH413, GH512, GH420, GH421, GH520, GH428, GH429, GH528) in the pixel groups (PG4, PG8, PG12, PG16) adjacent to the pixel groups (PG2, PG6, PG10, PG14) in the first direction may have an arrangement pattern formed in the shape of “┌”.

The pixel array 110 according to the present embodiment may include pixels (PX) having different photosensitivities for HDR implementation. The pixels (PXs) having the same photosensitivity may be arranged symmetrically to each other in adjacent pixel groups (PG1~PG16) in order to implement autofocus. Here, the arrangement patterns being symmetrical to each other in the first direction may mean that the centers of the corresponding arrangement patterns are located on the same series of arrangement patterns in the first direction, and the arrangement patterns being symmetrical to each other in the second direction may mean that the centers of the corresponding arrangement patterns are located on the same series of arrangement patterns in the second direction.

The pixel groups (PG1~PG16) arranged as in FIGS. 6A to 6D may be formed at various positions within the pixel array 110, and the number of pixel groups (PG1~PG16) is not limited thereto. In addition, the positions of the high-sensitivity pixels and the positions of the low-sensitivity pixels may be interchanged in the arrangement structure of FIGS. 6A to 6D. For example, the low-sensitivity pixels may be formed at the positions of the high-sensitivity pixels shown in FIGS. 6A to 6D, and the high-sensitivity pixels may be formed at the positions of the low-sensitivity pixels shown in FIGS. 6A to 6D. In addition, the arrangement pattern of the high-sensitivity pixels in the pixel groups (PG1~PG16) may be changed to a different shape within a range within which the arrangement patterns of the high-sensitivity pixels of the pixel groups (PG1~PG16) are symmetrical to each other in the first direction and the second direction.

FIGS. 7A to 7D are diagrams illustrating operations for describing an offset of the pixel group in the offset setting circuit of FIG. 3 based on some embodiments of the present disclosure.

Referring to FIG. 7A, the offset setting circuit 131 may set an offset based on the positions of the pixel blocks (PXB1~PXB4).

The offset setting circuit 131 may set an offset not only using the low-sensitivity pixel (GL00) of the pixel group (PG1) in the pixel block (PXB1) but also using the low-sensitivity pixel (GL50) of the pixel group (PG2) located closest to the pixel group (PG1) in the second direction (i.e., a vertical direction). For example, the offset setting circuit 131 may set an offset by summing the pixel value of the low-sensitivity pixel (GL00) of the pixel group (PG1) and the pixel value of the low-sensitivity pixel (GL50) of the pixel group (PG2) among the pixels arranged in the left column (L1) in the pixel block (PXB1). Here, the term “pixel value” may mean the pixel signal described above. And, the term “summing” may refer to a process of adding (or averaging) the pixel values (or pixel signals) of the pixels. For example, the offset (OS) of the left column (L1) may be defined as “1L”.

The offset setting circuit 131 may set the offset not only using the low-sensitivity pixel (GL05) of the pixel group (PG3) in the pixel block (PXB1) but also using the low-sensitivity pixel (GL55) of the pixel group (PG4) located closest to the pixel group (PG3) in the second direction (i.e., a vertical direction). For example, the offset setting circuit 131 may set the offset by summing the pixel value of the low-sensitivity pixel (GL05) of the pixel group (PG3) and the pixel value of the low-sensitivity pixel (GL55) of the pixel group (PG4) among the pixels arranged in the right column (R2) in the pixel block (PXB1). For example, the offset (OS) of the right column (R2) may be defined as “1R”.

Referring to FIG. 7B, the offset setting circuit 131 may set the offset not only using the low-sensitivity pixel (GL08) of the pixel group (PG5) in the pixel block (PXB2) but also using the low-sensitivity pixel (GL58) of the pixel group (PG6) located closest to the pixel group (PG6) in the second direction (i.e., a vertical direction). For example, the offset setting circuit 131 may set the offset by summing the pixel value of the low-sensitivity pixel (GL08) of the pixel group (PG5) and the pixel value of the low-sensitivity pixel (GL58) of the pixel group (PG6) among the pixels arranged in the left column (L3) in the pixel block (PXB2). For example, the offset (OS) of the left column (L3) may be defined as “2L”.

The offset setting circuit 131 may set the offset not only using the low-sensitivity pixel (GL013) of the pixel group (PG7) in the pixel block (PXB2) but also using the low-sensitivity pixel (GL513) of the pixel group (PG8) located closest to the pixel group (PG7) in the second direction (i.e., a vertical direction). For example, the offset setting circuit 131 may set the offset by summing the pixel value of the low-sensitivity pixel (GL013) of the pixel group (PG7) and the pixel value of the low-sensitivity pixel (GL513) of the pixel group (PG8) among the pixels arranged in the right column (L4) in the pixel block (PXB2). For example, the offset (OS) of the right column (R4) may be defined as “2R”.

Referring to FIGS. 7C and 7D, it can be understood that the offset setting circuit 131 can set the offset (OS) in the pixel blocks (PXB3, PXB4) in the same manner as described above.

Referring to FIG. 7C, the offset setting circuit 131 may set the offset by summing the pixel values of the low-sensitivity pixel (GL016, GL516) of the pixel groups (PG9, PG10) arranged in the left column (L5) in the pixel block (PXB3). For example, the offset (OS) of the left column (L5) may be defined as “3L”. The offset setting circuit 131 may set the offset by summing the pixel values of the low-sensitivity pixel (GL021, GL521) of the pixel groups (PG11, PG12) arranged in the right column (R6) in the pixel block (PXB3). For example, the offset (OS) of the right column (R6) may be defined as “3R”.

Referring to FIG. 7D, the offset setting circuit 131 may set the offset by summing the pixel values of the low-sensitivity pixel (GL024, GL524) of the pixel groups (PG13, PG14) arranged in the left column (L7) in the pixel block (PXB4). For example, the offset (OS) of the left column (L7) may be defined as “4L”. The offset setting circuit 131 may set the offset by summing the pixel values of the low-sensitivity pixel (GL029, GL529) of the pixel groups (PG15, PG16) arranged in the right column (R8) in the pixel block (PXB4). For example, the offset (OS) of the right column (R8) may be defined as “4R”.

As illustrated above, the respective offsets xL and xR, where x is a natural number greater than 1, of left and right columns L(2x−1) and R(2x), which are arranged in the pixel blocks (PXBx), may be defined as relative distances with reference to reference columns, i.e., the left and right columns L1 and R2, which are arranged in the leftmost pixel block (PXB1) are defined to have the offsets 1L and 1R (see FIG. 7A).

In the present disclosure, the position of the pixel block (PXB1) located at the leftmost position in the first direction is set to a reference position for convenience of description. As a result, since the offset of the left and right columns L1 and R2 arranged in the pixel block (PXB1) is set to “1L” and “1R”, the offset value may be defined as “1”. In addition, the offset of the left and right columns L3 and R4 arranged in the pixel block (PXB2) located relatively most adjacent (closest) to the pixel block (PXB1) is set to “2L” and “2R”, so that the offset value may be defined as “2”. In addition, the offset of the left and right columns L5 and R6 arranged in the pixel block (PXB3) located second adjacent to the pixel block (PXB1) is set to “3L” and “3R”, so that the offset value may be defined as “3”. The offset of the left and right columns L7 and R8 arranged in the pixel block (PXB4) located third adjacent (relatively farthest from) to the pixel block (PXB1) is set to “4L” and “4R”, so the offset value may be defined as “4”.

As discussed above, the offset value of pixel block PXBx, where x is a natural number, may be defined according to the offsets xL and xR of left and right columns arranged in the pixel block PXBx.

That is, it can be seen that, as the distance between a target pixel block and the reference pixel block (PXB1) located at the reference position becomes shorter, the offset value of the corresponding pixel block is set to a smaller offset value, and as the distance between the target pixel block and the reference pixel block (PXB1) becomes longer, the offset value of the corresponding pixel block is set to a higher offset value.

FIG. 8 is a diagram illustrating operations for the phase-difference adjuster 130 of FIG. 3 based on some embodiments of the present disclosure.

Referring to FIGS. 7A to 7D and FIG. 8 described above, the phase-difference adjuster 130 may generate a left image using low-sensitivity pixels arranged on the left columns of different pixel blocks (PXB1~PXB4). In addition, the phase-difference adjuster 130 may generate a right image using low-sensitivity pixels arranged on the right columns of different pixel blocks (PXB1~PXB4).

In order to adjust a phase difference according to a difference in baseline length, the phase-difference adjuster 130 may mix the right image when generating the left image or may mix the left image when generating the right image.

A process (LIC) of generating the left image by the phase-difference adjuster 130 will hereinafter be described in more detail. The phase-difference adjuster 130 may generate the left image not only using low-sensitivity pixels (GL00, GL50, GL016, GL516) arranged in the left columns (L1, L5) of two pixel blocks (PXB1, PXB3) arranged on both sides of the pixel block (PXB2), but also using low-sensitivity pixels (GL13, GL513) arranged in the right column (R4) of the pixel block (PXB2) arranged between the two pixel blocks (PXB1, PXB3).

That is, the phase-difference adjuster 130 may generate a left image by using a first value (S1) obtained by summing pixel values of the low-sensitivity pixels (GL00, GL50) arranged on the left column (L1) of the pixel block (PXB1), a second value (S2) obtained by summing pixel values of the low-sensitivity pixels (GL013, GL513) arranged on the right column (R4) of the pixel block (PXB2), and a third value (S3) obtained by summing pixel values of the low-sensitivity pixels (GL016, GL516) arranged on the left column (L5) of the pixel block (PXB3). That is, the phase-difference adjuster 130 may generate the left image by summing the first to third values (S1, S2, S3).

A process (RIC) of generating the right image by the phase-difference adjuster 130 will hereinafter be described in more detail. The phase-difference adjuster 130 may generate the right image not only using low-sensitivity pixels (GL013, GL513, GL029, GL529) arranged in the right columns (R4, R8) of two pixel blocks (PXB2, PXB4) arranged on both sides of the pixel block (PXB3), but also using low-sensitivity pixels (GL016, GL516) arranged in the left column (L5) of the pixel block (PXB3) arranged between the two pixel blocks (PXB2, PXB4).

That is, the phase-difference adjuster 130 may generate a right image by using a fourth value (S4) obtained by summing pixel values of the low-sensitivity pixels (GL013, GL513) arranged on the right column (R4) of the pixel block (PXB2), a fifth value (S5) obtained by summing pixel values of the low-sensitivity pixels (GL016, GL516) arranged on the left column (L5) of the pixel block (PXB3), and a sixth value (S6) obtained by summing pixel values of the low-sensitivity pixels (GL029, GL529) arranged on the right column (R8) of the pixel block (PXB4). That is, the phase-difference adjuster 130 may generate the right image by summing the fourth to sixth values (S4, S5, S6).

For convenience of description, the embodiments of the present disclosure have disclosed cases in which the left image is generated using three values (S1~S3) and the right image is generated using three values (S4~S6), but the embodiments of the present disclosure are not limited thereto. In another embodiment, the left image may be generated by further using other pixel groups in which low-sensitivity pixels are located at the left side of the pixel group, or the right image may be generated by further using other pixel groups in which low-sensitivity pixels are located at the right side of the pixel group.

In the process (LIC) of generating the left image, the offset setting circuit 131 may determine the offset (OS1) using the following equation 1.

(1+2+3)/3=2 [Equation 1]

Referring to Equation 1 and FIGS. 7A to 7D, the offset value “1” of the pixel block (PXB1), the offset value “2” of the pixel block (PXB2), and the offset value “3” of the pixel block (PXB3) are summed, and the sum value “6” is divided by “3” (i.e., the number of pixel blocks), so that the offset (OS1) may become “2”.

In the process (RIC) of generating the right image, the offset setting circuit 131 may determine the offset (OS2) using the following equation 2.

(2+3+4)/3=3 [Equation 2]

Referring to Equation 2 and FIGS. 7A to 7D, the offset value “2” of the pixel block (PXB2), the offset value “3” of the pixel block (PXB3), and the offset value “4” of the pixel block (PXB4) are summed, and the sum value “9” is divided by “3” (i.e., the number of pixel blocks), so that the offset (OS2) may become “3”.

Accordingly, since the offset (OS2) when generating the right image is “3” and the offset (OS1) when generating the left image is “2”, the offset setting circuit 131 may set the value “1” corresponding to a difference value between the offsets (OS2, OS1) as the offset value corresponding to a phase difference between the right image and the left image.

In the process (LIC) of generating the left image, the baseline adjuster 132 can calculate the baseline length using the following equation 3.

(0+1+0)/3=1/3 [Equation 3]

In the process (RIC) of generating the right image, the baseline adjuster can calculate the baseline length using the following equation 4.

(1+0+1)/3=2/3 [Equation 4]

As can be seen from Equation 3 and Equation 4 above, the baseline adjuster 132 can assign the number “0” to the left image and the number “1” to the right image to distinguish between the left image and the right image. The mixture of the left image and the right image can be their average value. Then, the length of the baseline of the left image may become “1/3” and the length of the baseline of the right image may become “2/3”. The right image has a longer baseline length than the left image.

The baseline adjuster 132 may adjust the baseline length in a direction toward an image having a shorter baseline length among the left image and the right image. Accordingly, the baseline adjuster 132 may adjust the baseline length of the right image to “1/3” in the same manner as in the baseline length of the left image.

FIGS. 9A to 9C are diagrams illustrating operations for the sign adjuster of FIG. 3 based on some embodiments of the present disclosure.

Referring to FIGS. 9A to 9C, the pixel group (PG) including four green color (G) pixels arranged in a (2×2) matrix structure will be described. In order to expand the dynamic range of the image sensing device 100, in the pixel group (PG), the number of high-sensitivity pixels may be much greater than the number of low-sensitivity pixels. For example, the pixel group (PG) may include four pixels (TL, TR, BL, BR) arranged in a (2×2) matrix structure. Three pixels denoted by “H” in the pixel group (PG) may be high-sensitivity pixels, and one pixel denoted by “L” may be a low-sensitivity pixel. In the embodiment of FIGS. 9A to 9C, descriptions overlapping with those of FIG. 2 will herein be omitted, and as such redundant descriptions thereof will be omitted for brevity.

Referring to FIG. 9A, a length (i.e., a baseline length) BL1 between the center of the low-sensitivity pixel (TL) of the pixel group (PG11) and the center of the low-sensitivity pixel (TR) of the pixel group (PG12) is set to “1”. The baseline direction between the low-sensitivity pixel (TL) located at the top-left side of the pixel group (PG11) and the low-sensitivity pixel (TR) located at the top-right side of the pixel group (PG12) is denoted by an arrow. That is, the baseline direction of the low-sensitivity pixels may be the right direction from the low-sensitivity pixel (TL) to the low-sensitivity pixel (TR).

Referring to FIG. 9B, the binning circuit 120 may bin at least three high-sensitivity pixels (HP1) arranged in a “┘” shape in the pixel group (PG11). In addition, the binning circuit 120 may bin at least three high-sensitivity pixels (HP2) arranged in an “└” shape in the pixel group (PG12). Here, the length (i.e., the baseline length BL2) between the center of the high-sensitivity pixels (HP1) and the center of the high-sensitivity pixels (HP2) is set to “−1/3”.

The baseline direction between the high-sensitivity pixels (HP1) of the pixel group (PG11) and the high-sensitivity pixels (HP2) of the pixel group (PG12) is denoted by an arrow shown in FIG. 9B. That is, the baseline direction of the high-sensitivity pixels may be the left direction from the high-sensitivity pixels (HP1) to the high-sensitivity pixels (HP2).

However, since the baseline length (BL1) between the low-sensitivity pixels (TL, TR) has a positive(+) value and the baseline length (BL2) between the high-sensitivity pixels (HP1, HP2) has a negative(−) value, the direction of the baseline (i.e., baseline direction) may be reversed. When the sign of the baseline is reversed, a disparity calculation error may occur when calculating the parallax later.

Accordingly, as shown in FIG. 9C, the sign adjuster 133 according to the present disclosure may move the effective position of the high-sensitivity pixels (HP1) of the pixel group (PG11) to the right and may move the effective position of the high-sensitivity pixels (HP2) of the pixel group (PG12) to the left, so that the baseline direction between the high-sensitivity pixels (HP1, HP2) can be reversed as compared to the direction of FIG. 9B. Here, moving the effective position of pixels may mean adjusting the operation sign during the process of summing pixel values of the pixels in order to reverse the baseline direction.

In this case, since the baseline between the high-sensitivity pixels (HP1, HP2) also has a positive(+) value in the same manner as in the baseline direction between the low-sensitivity pixels (TL, TR), disparity calculation errors can be prevented.

The phase-difference images (PDIMG) generated according to the offset determined by the offset setting circuit 131, the baseline length adjusted by the baseline adjuster 132, and the baseline direction adjusted by the sign adjuster 133 can be transmitted to the parallax image generator 140.

As is apparent from the above description, the image sensing device according to the embodiments of the present disclosure can improve autofocus accuracy by reducing the amount of parallax between the high-sensitivity image and the low-sensitivity image.

The embodiments of the present disclosure may provide a variety of advantageous effects capable of being directly or indirectly recognized by one of ordinary skill in the art.

Although a number of illustrative embodiments have been described, it should be understood that modifications and enhancements to the disclosed embodiments and other embodiments can be devised based on what is described and/or illustrated in the present disclosure. Therefore, the scope of the present disclosure should not be limited to the above-described embodiments but should include the equivalents thereof. Furthermore, the embodiments may be combined to form additional embodiments.

What is claimed is:

1. An image sensing device comprising:
a plurality of pixel blocks, each of which includes a plurality of pixel groups arranged in a Bayer pattern;
a binning circuit configured to bin pixels included in the plurality of pixel groups; and
a phase-difference adjuster configured to generate a left image and a right image based on images received from the plurality of pixel blocks and the binning circuit, and configured to adjust a baseline length between the left image and the right image,
wherein:
each of the plurality of pixel groups includes a first pixel having a first photosensitivity and a plurality of second pixels having a second photosensitivity; and
the phase-difference adjuster includes a baseline adjuster configured to adjust the baseline length between the first pixels located in different pixel blocks among the plurality of pixel blocks.

2. The image sensing device according to claim 1, wherein the first pixel and the plurality of second pixels are configured to share one microlens in each of the plurality of pixel groups.

3. The image sensing device according to claim 1, wherein the binning circuit is configured to bin the plurality of second pixels.

4. The image sensing device according to claim 1,
wherein each of the plurality of pixel blocks includes:
a plurality of first pixel groups;
a plurality of second pixel groups arranged adjacent to the first pixel groups in a first direction;
a plurality of third pixel groups arranged adjacent to the first pixel groups in a second direction; and
a plurality of fourth pixel groups arranged adjacent to the third pixel groups in the first direction, and
wherein:
an arrangement pattern of the first pixel groups is symmetrical to an arrangement pattern of the second pixel groups in the first direction; and
an arrangement pattern of the third pixel groups is symmetrical to an arrangement pattern of the fourth pixel groups in the first direction.

5. The image sensing device according to claim 4, wherein:
each of the first pixel groups is configured such that the first pixel and the plurality of second pixels are arranged in a (2×2) matrix structure, and
the first pixel is located at a top-left side of each first pixel group.

6. The image sensing device according to claim 4, wherein:
each of the second pixel groups is configured such that the first pixel and the plurality of second pixels are arranged in a (2×2) matrix structure, and
the first pixel is located at a top-right side of each second pixel group.

7. The image sensing device according to claim 4, wherein:
each of the third pixel groups is configured such that the first pixel and the plurality of second pixels are arranged in a (2×2) matrix structure, and
the first pixel is located at a bottom-left side of each third pixel group.

8. The image sensing device according to claim 4, wherein:
each of the fourth pixel groups is configured such that the first pixel and the plurality of second pixels are arranged in a (2×2) matrix structure, and
the first pixel is located at a bottom-right side of each fourth pixel group.

9. The image sensing device according to claim 1, further comprising an offset setting circuit configured to set an offset differently according to a position of the first pixel in the plurality of pixel blocks.

10. The image sensing device according to claim 9, wherein the offset setting circuit is configured such that, as a distance from a single pixel block serving as a reference among the plurality of pixel blocks becomes longer, an offset value is set to a higher offset.

11. The image sensing device according to claim 9, wherein the offset setting circuit is configured to set an offset value by using pixel values of at least two first pixels included in different pixel groups in each of the plurality of pixel blocks.

12. The image sensing device according to claim 11, wherein:
the offset setting circuit sets a left offset value by calculating a sum of pixel values of two first pixels adjacent to each other in a second direction, which are arranged on a left column in each of the plurality of pixel groups; and
the offset setting circuit sets a right offset value by calculating a sum of pixel values of two first pixels adjacent to each other in the second direction, which are arranged on a right column in each of the plurality of pixel groups.

13. The image sensing device according to claim 1, wherein the plurality of pixel blocks includes:
a first pixel block;
a second pixel block arranged adjacent to the first pixel block in a first direction;
a third pixel block arranged adjacent to the second pixel block in the first direction; and
a fourth pixel block arranged adjacent to the third pixel block in the first direction.

14. The image sensing device according to claim 13, wherein the phase-difference adjuster is configured to:
calculate a first value by summing pixel values of two first pixels located on a first left column in each of pixel groups included in the first pixel block;
calculate a second value by summing pixel values of two first pixels located on a first right column in each of pixel groups included in the second pixel block;
calculate a third value by summing pixel values of two first pixels located on a second left column in each of pixel groups included in the third pixel block; and
generate the left image by summing the first value, the second value, and the third value.

15. The image sensing device according to claim 13, wherein the phase-difference adjuster is configured to:
calculate a fourth value by summing pixel values of two first pixels located on a second right column in each of pixel groups included in the second pixel block;
calculate a fifth value by summing pixel values of two first pixels located on a third left column in each of pixel groups included in the third pixel block;
calculate a sixth value by summing pixel values of two first pixels located on a third right column in each of pixel groups included in the fourth pixel block; and
generate the right image by summing the fourth value, the fifth value, and the sixth value.

16. The image sensing device according to claim 13, wherein the baseline adjuster is configured to:
calculate a baseline length of the left image by summing a left image of the first pixel block, a right image of the second pixel block, and a left image of the third pixel block; and
calculate a baseline length of the right image by summing a right image of the second pixel block, a left image of the third pixel block, and a right image of the fourth pixel block.

17. The image sensing device according to claim 16, wherein the baseline adjuster is configured to:
calculate the baseline length by allocating a first value to the left image and allocating a second value to the right image; and
adjust the baseline length in a direction toward an image having a shorter baseline length among the left image and the right image.

18. The image sensing device according to claim 1, wherein the phase-difference adjuster further includes a sign adjuster configured to adjust a baseline direction between the plurality of second pixels included in different pixel groups to be identical to a baseline direction between the first pixels.

19. The image sensing device according to claim 18, wherein:
a first pixel group among the plurality of pixel groups is configured such that the first pixel and the plurality of second pixels are arranged in a (2×2) matrix structure and the first pixel is located at a top-left side of each first pixel group;
a second pixel group among the plurality of pixel groups is configured such that the first pixel and the plurality of second pixels are arranged in a (2×2) matrix structure and the first pixel is located at a top-right side of each second pixel group; and
the baseline adjuster is configured to:
calculate a length between a center of the first pixel included in the first pixel group and a center of the first pixel included in the second pixel group as a first baseline length; and
calculate a length between a center of the second pixels included in the first pixel group and a center of the second pixels included in the second pixel group as a second baseline length.

20. The image sensing device according to claim 19, wherein the sign adjuster is configured to reverse the baseline direction by adjusting an operation sign when the plurality of second pixels included in the first pixel group and the plurality of second pixels included in the second pixel group are summed.
